(19) United States
(12) Patent Application Publication
(10) Pub. No.: US 2018/0269168 A1
(43) Pub. Date: Sep. 20, 2018

(54) MODULE SUBSTRATE

(71) Applicant: Panasonic Corporation, Osaka (JP)

(72) Inventor: KOICHI MIZUNO, Kanagawa (JP)

(21) Appl. No.: 15/885,922

(22) Filed: Feb. 1, 2018

(30) Foreign Application Priority Data
Mar. 15, 2017 (JP) 2017-050108

(51) Int. Cl. H01L 23/66; H01L 23/498; H01P 3/12

(52) U.S. Cl. CPC H01L 23/66; H01L 23/49822; H01L 24/16; H01P 3/121; H01L 2223/6627; H01L 23/49838

(57) ABSTRACT

A module substrate includes a surface layer to which a rectangular waveguide structure having a waveguide aperture is to be connected; metal layers stacked with a dielectric layer between each pair thereof and including a first metal layer that includes a transmission line and a coupling element at a portion of the transmission line and a second metal layer positioned further than the first metal layer from the rectangular waveguide structure; and vias connecting the adjacent metal layers. The surface layer has a first opening facing the waveguide aperture. The first opening surrounds the coupling element in plan view from the surface layer. A dielectric layer region surrounded by some of the vias is formed within a projection area of the first opening between the first and second metal layers. The region has a size smaller than the waveguide aperture in the plan view.

### BACKGROUND

### 1. Technical Field

The present disclosure relates to module substrates. Specifically, the present disclosure relates to a module substrate that realizes, as an antenna element, a combination of a waveguide and an integrated circuit.

### 2. Description of the Related Art

With the recent availability of broadband signals, a high-speed wireless communication system or a high-resolution radar system using a frequency of 100 GHz or higher has been examined. For example, forming a front-end circuit for a high-speed wireless communication system using a 300-GHz band or a high-resolution radar system using a 140-GHz band into an integrated circuit has been attempted.

For the emission of high-frequency signals (radio signals) into space or the collection of electric power in space by using an existing wireless communication system or an existing radar system, coupling of an antenna element with an integrated circuit has been examined.

For example, U.S. Pat. No. 8,912,858 (hereinafter referred to as Patent Document 1) examines a connection between an antenna element and an integrated circuit for the emission of high-frequency signals into space or the collection of electric power in space.

### SUMMARY

However, the technology described in Patent Document 1 is insufficient for emitting signals in the 100-GHz band or higher into space or collecting electric power in space.

One non-limiting and exemplary embodiment of the present disclosure provides a module substrate capable of emitting signals in the 100-GHz band or higher into space or collecting electric power in space highly efficiently with low loss.

In one general aspect, the techniques disclosed here feature a module substrate including a surface layer to which a rectangular waveguide structure having a waveguide aperture is to be connected; a plurality of metal layers that are stacked with a dielectric layer between each adjacent pair of the metal layers, the plurality of metal layers including a first metal layer including a transmission line and a coupling element formed at a portion of the transmission line and a second metal layer positioned further than the first metal layer from the rectangular waveguide structure; and a plurality of vias each connecting a corresponding adjacent pair of the metal layers to each other. The surface layer has a first opening that is to be located to face the waveguide aperture. The first opening surrounds the coupling element in a plan view from the surface layer. A region of the dielectric layer is formed within an area in which the first opening is projected between the first metal layer and the second metal layer. The region is surrounded by some of the plurality of vias. The size of the region in the plan view is smaller than the size of the waveguide aperture.

A module substrate according to an embodiment of the present disclosure can emit signals in the 100-GHz band or higher into space or collect electric power in space highly efficiently with low loss.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 illustrates an example of a connection between a waveguide and a transmission line in existing techniques;

FIG. 2A illustrates a section S1 of FIG. 1;

FIG. 2B illustrates a section S2 of FIG. 1;

FIG. 3 is a table showing the relations among the standard of a rectangular waveguide for a high frequency band, the wavelength of an electromagnetic wave, dimensional tolerance achievable with an existing machining method, and dimensional tolerance achievable with a high-precision machining method;

FIG. 4 is a plan view of an example of a module substrate according to a first embodiment of the present disclosure;

FIG. 5A is a sectional view taken along line VA-VA of FIG. 4;

FIG. 5B is a sectional view taken along line VB-VB of FIG. 4;

FIG. 5C is a sectional view taken along line VC-VC of FIG. 4;

FIG. 6 is a table showing the relation between each standard size of a rectangular waveguide for a high frequency band and the size of the rectangular waveguide in accordance with a dielectric constant;

FIG. 7A illustrates an example of a structure for connecting a CMOS chip and a rectangular waveguide to the module substrate;

FIG. 7B illustrates the example of the structure for connecting the CMOS chip and the rectangular waveguide to the module substrate;

FIG. 8 illustrates an example of the electromagnetic structure of the module substrate according to the first embodiment of the present disclosure;

FIG. 9 is a plan view of an example of a module substrate according to a second embodiment of the present disclosure;

FIG. 10A is a sectional view taken along line XA-XA of FIG. 9;

FIG. 10B is a sectional view taken along line XB-XB of FIG. 9;

FIG. 100 is a sectional view taken along line XC-XC of FIG. 9;

FIG. 11 illustrates an example of an electromagnetic structure of the module substrate according to the second embodiment of the present disclosure;

FIG. 12 is a plan view of an example of a module substrate according to a third embodiment of the present disclosure;

FIG. 13A is a sectional view taken along line XIIIA-XIIIA of FIG. 12;

FIG. 13B is a sectional view taken along line XIIIB-XIIIB of FIG. 12;

FIG. 13C is a sectional view taken along line XIIIC-XIIIC of FIG. 12;

FIG. 14 is a sectional view of an example of a module substrate according to a fourth embodiment of the present disclosure;

FIG. 15 illustrates an example of an electromagnetic structure of the module substrate according to the fourth embodiment of the present disclosure;

FIG. 16 is a sectional view of an example of a module substrate according to a fifth embodiment of the present disclosure; and

FIG. 17 illustrates an example of an electromagnetic structure of the module substrate according to the fifth embodiment of the present disclosure.

### DETAILED DESCRIPTION

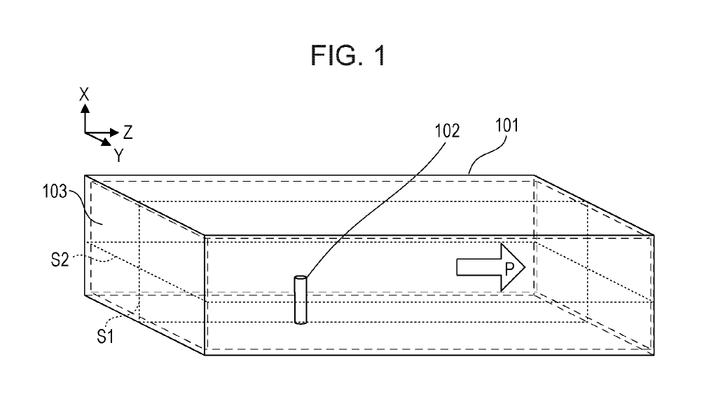

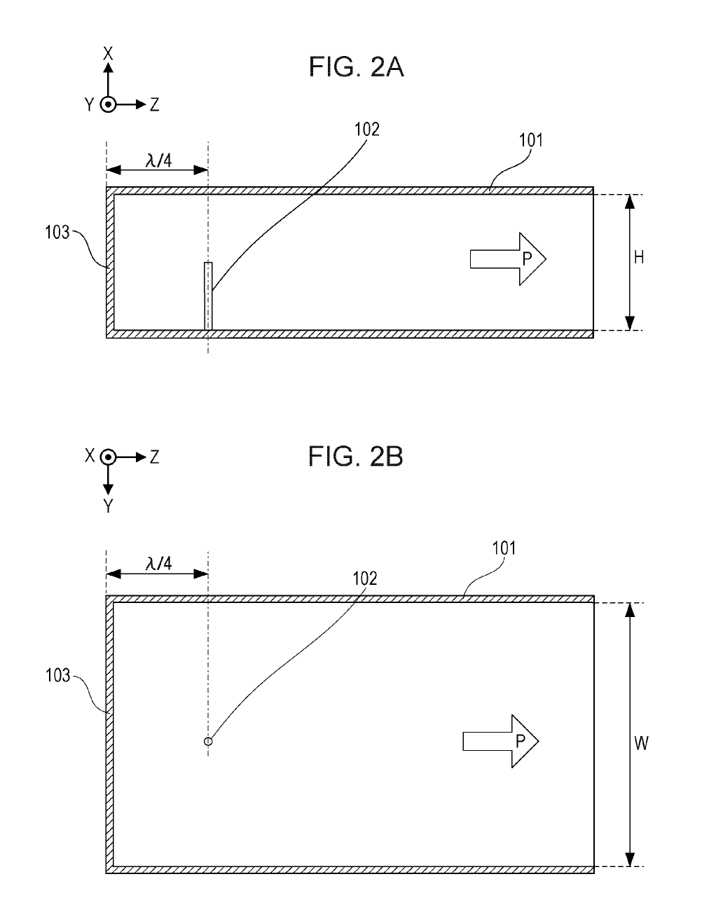

FIG. 1 illustrates an example of a connection between a waveguide and a transmission line in existing techniques. FIG. 2A illustrates a section S1 of FIG. 1. FIG. 2B illustrates a section S2 of FIG. 1. A coaxial line is used as a transmission line for a frequency band such as a microwave band. For such a frequency band, the coaxial line and a waveguide are connected as illustrated in FIG. 1, FIG. 2A, and FIG. 2B. FIG. 1, FIG. 2A, and FIG. 2B illustrate a waveguide 101, a coupling element 102, and a reflection surface 103. In the structure illustrated in each of FIG. 1, FIG. 2A, and FIG. 2B, the coupling element 102 inserted in the positive direction of the X-axis into the waveguide 101 emits an electromagnetic wave, and electric power propagates in the positive direction of the Z-axis.

The coupling element 102 is a center conductor of a coaxial line inserted into the waveguide 101 through a lower surface thereof. The coupling element 102 is inserted as a dipole antenna. The electromagnetic wave emitted from the coupling element 102 propagates in both directions (positive and negative directions of the Z-axis) inside the waveguide 101 in the TE01 mode.

The reflection surface 103 is formed by short-circuiting one end of the waveguide 101. Hereinafter, the reflection surface 103 will be referred to as a backshort 103, as appropriate. The backshort 103 reflects the electromagnetic wave that propagates in a direction opposite (negative direction of the Z-axis) to a power propagation direction P after emitted from the coupling element 102.

For example, in a case where the distance between the coupling element 102 and the backshort 103 is ¼ the wavelength λ of the electromagnetic wave, the electromagnetic wave reflected on the backshort 103 becomes an electromagnetic wave having a phase difference of 2π at the position of the coupling element 102. The reflected electromagnetic wave then combines, in the same phase, with the electromagnetic wave emitted in the power propagation direction P from the coupling element 102, and the combined electromagnetic wave travels in the power propagation direction P. As a result, electromagnetic field coupling from the coupling element 102 to the waveguide 101 is efficiently formed at a frequency at which the distance between the coupling element 102 and the backshort 103 is ¼ the wavelength λ of the electromagnetic wave.

In a high-frequency circuit that uses a semiconductor integrated circuit, a high-frequency signal (radio frequency signal) is mainly transmitted to an output terminal on a semiconductor chip along a planar transmission line, such as a microstrip line or a coplanar waveguide, formed on the semiconductor chip. The output terminal on the semiconductor chip is connected to the planar transmission line formed on a resin substrate. The high-frequency signal that propagates along the transmission line is connected to an emission element, such as an antenna, through the output terminal. In other words, this is a coupling structure for coupling the planar transmission line formed on the resin substrate and the waveguide structure.

Patent Document 1 discloses a backshort in a structure for coupling an integrated circuit and a waveguide. Patent Document 1 describes that a high-frequency output of the integrated circuit is transmitted along a microstrip line formed on a millimeter-wave substrate so as to be positioned above a rectangular hole that opens in a resin substrate (printed circuit board (PCB)). In Patent Document 1, the backshort having a shape that covers the millimeter-wave substrate is independently formed and disposed opposite the microstrip line. In the above structure, the backshort has the same size as the waveguide.

An existing waveguide coupling structure is used for, for example, a wavelength of approximately 10 cm in the microwave band and a wavelength of approximately 1 cm at 30 GHz, which is in the millimeter-wave band. Therefore, the existing waveguide coupling structure is a structure that is two orders of magnitude larger with respect to an alignment precision that can be obtained with a mechanism manufactured using a workpiece tolerance (for example, ±0.1 mm) achievable with machining according to existing techniques. Thus, the machining precision and aligning precision for the coupling structure are achievable with existing techniques.

However, an electromagnetic wave having a frequency of 100 GHz or higher has a wavelength of 1 to 3 mm. Thus, it is difficult to achieve a sufficient precision in alignment by machining or mechanical mechanisms employing existing techniques.

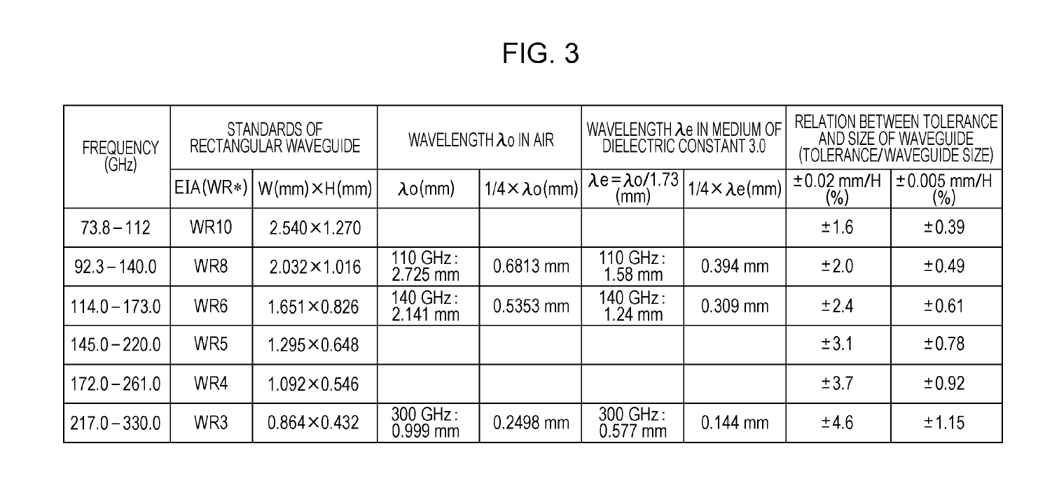

FIG. 3 is a table showing the relations among the standard of a rectangular waveguide for a high frequency band (radio frequency band), the wavelength of an electromagnetic wave, dimensional tolerance (±0.02 mm) in an existing machining method, and dimensional tolerance (±0.005 mm) achievable with a high-precision machining method. FIG. 3 shows standard names and each standard size of a waveguide in accordance with the Electronic Industries Alliance (EIA) standards corresponding to each frequency band. In addition, FIG. 3 shows one wavelength and ¼ wavelength of an electromagnetic wave of a typical frequency in air and one wavelength and ¼ wavelength of the electromagnetic wave of the typical frequency in a medium having a dielectric constant of 3.0. FIG. 3 also shows a ratio of the dimensional tolerance to each standard size of the waveguide.

The size (width direction W×height direction H) of an inner wall in WR3, which is the standard for the rectangular waveguide in the 300-GHz band, is 0.864 mm×0.432 mm. In a case where a transmission line is disposed at a position set in the rectangular waveguide with a precision of approximately ±1% with respect to the size of the rectangular waveguide, the alignment precision is ±0.005 mm in the X-axis direction (height direction H). In a case where a backshort having ¼ wavelength is used in a propagation direction of an electromagnetic wave, an alignment precision required for forming the backshort with the precision of approximately ±1% is ±0.0025 mm in the Z-axis direction.

To achieve such alignment precisions in a structure formed by machining, a high-precision machining method and a high-precision alignment mechanism are required. Thus, a decrease in manufacturing yields and an increase in manufacturing costs are expected.

Compared with the general machining method and mechanical positioning method described above, a patterning method that involves a build-up process and a semi-additive process, which are used to manufacture resin multilayer substrates and semiconductor packages, can achieve a precision one order of magnitude higher with respect to the dimensional tolerance achievable with the existing machining method. Thus, a desired alignment precision is expected to be achieved by a simple method, when the resin multilayer substrate and the waveguide are combined to form a waveguide connection structure.

However, the dielectric constant of a resin material is higher than that of the air and thus causes discontinuity between the dielectric constant of the air, which is the medium in the waveguide, and the dielectric constant of the resin material, which is the medium of the resin multilayer substrate. Such discontinuity causes impedance mismatching. Therefore, measures to reduce the impedance mismatching have been examined in order to achieve efficient electromagnetic coupling (connection as a medium for transmitting high-frequency signals) between the transmission line and the waveguide.

To address such circumstances, the present disclosure provides a module substrate that includes a resin multilayer substrate and is capable of emitting signals in the 100-GHz band or higher into space or collecting electric power in space highly efficiently with low loss in a high-frequency communication system or a radar system that handles the signals in the 100-GHz band or higher.

Hereinafter, embodiments according to the present disclosure will be described in detail with the reference of the drawings. It is to be noted that the embodiments to be described below are examples and do not limit the present disclosure.

### First Embodiment

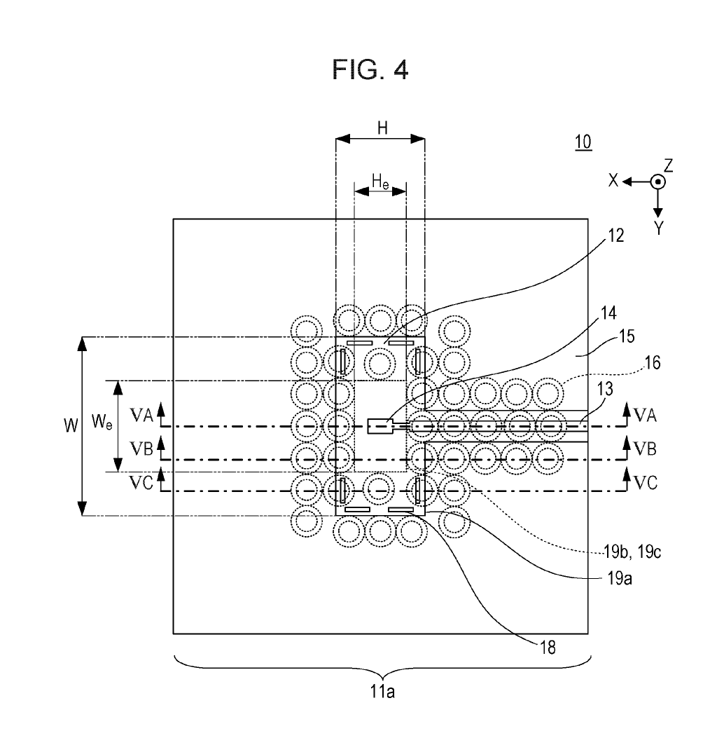

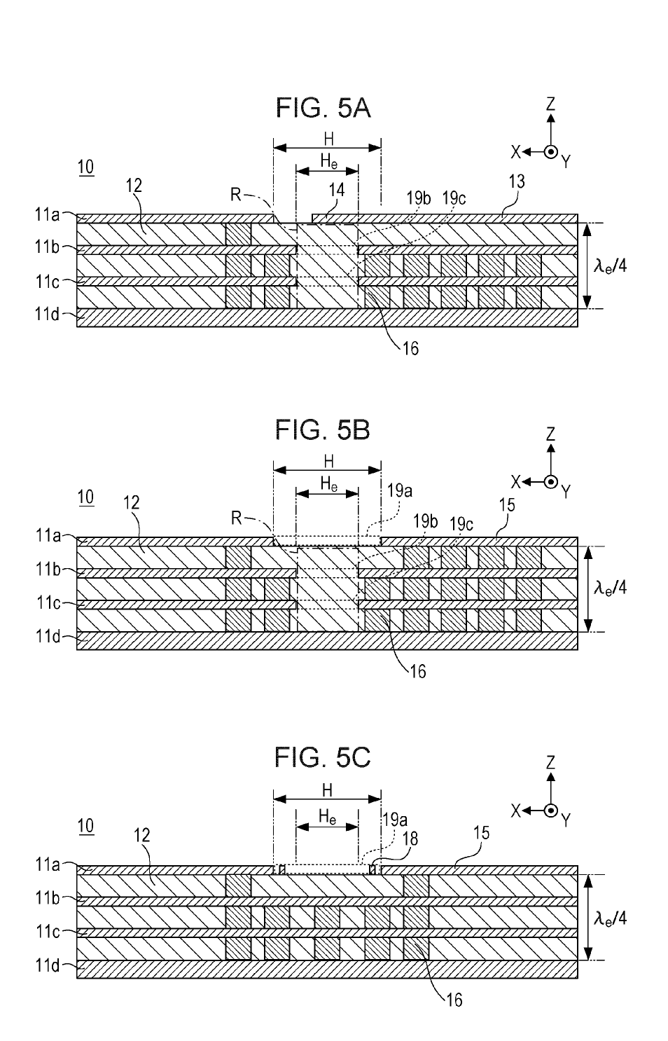

FIG. 4 is a plan view of an example of a module substrate 10 according to a first embodiment of the present disclosure. FIG. 5A is a sectional view taken along line VA-VA of FIG. 4. FIG. 5B is a sectional view taken along line VB-VB of FIG. 4. FIG. 5C is a sectional view taken along line VC-VC of FIG. 4.

The module substrate 10 includes four metal layers (wiring layers 11a to 11d) and dielectric layers 12 between the metal layers. The module substrate 10 is formed as a multilayer substrate by, for example, a build-up process. The four metal layers (wiring layers 11a to 11d) are stacked with the dielectric layer 12 between each adjacent pair of the metal layers.

The wiring layer 11a is a surface layer of the module substrate 10 and includes a transmission line 13, a coupling element 14, a ground plane 15, and alignment markers 18.

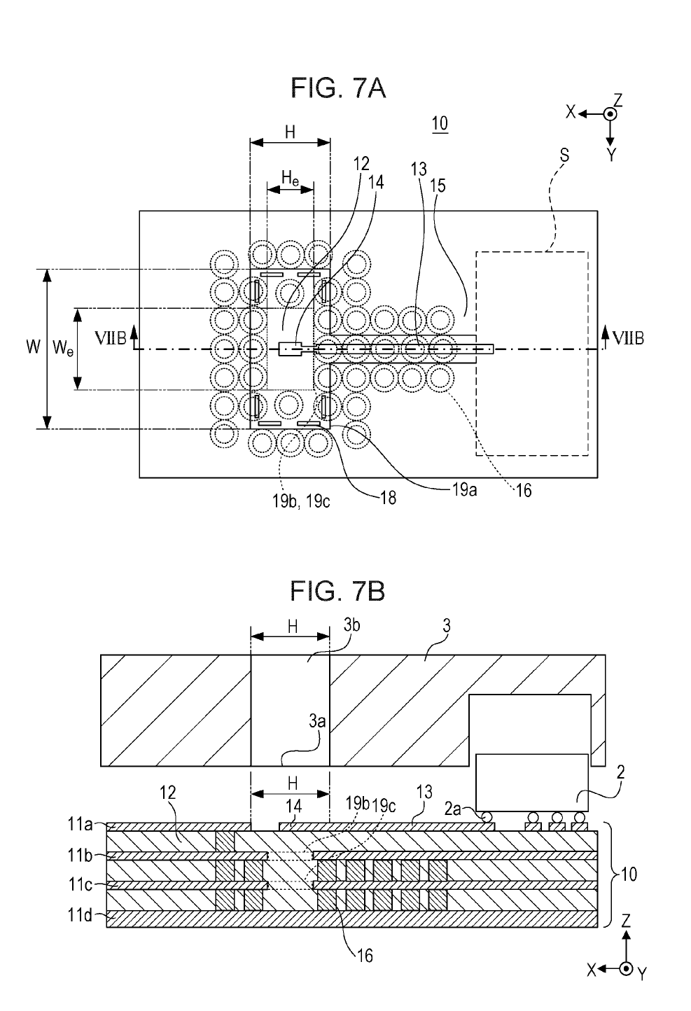

The transmission line 13 is formed on the wiring layer 11a and connected to high-frequency terminals 2a (see FIG. 7B) of a CMOS chip 2.

The coupling element 14 is formed at a position at an end portion of the transmission line 13. The position is opposite a waveguide aperture 3a (see FIG. 7B) of a rectangular waveguide structure 3.

The ground plane 15 is formed adjacent to both sides (in the positive and negative directions of the Y-axis) of the transmission line 13. The ground plane 15 is connected to the wiring layers 11a to 11d through via structures 16.

A portion of the wiring layer 11a surrounding the coupling element 14 and excluding the alignment markers 18 is removed from the wiring layer 11a. The portion has the same shape as the waveguide aperture 3a (see FIG. 7B) of the rectangular waveguide structure 3. Hereinafter, an area in which such a portion has been removed in a metal layer is referred to as an opening. That is, the wiring layer 11a has an opening 19a that surrounds the coupling element 14 and that has the same shape as the waveguide aperture 3a of the rectangular waveguide structure 3 except for the alignment markers 18. The opening 19a has a length H in the X-axis direction and a length W in the Y-axis direction. The inside of the opening of each of the metal layers may be void or may be filled with the dielectric layer 12.

The alignment markers 18 are metal patterns formed inside the opening 19a.

The wiring layer 11b and the wiring layer 11c, which are positioned below (negative direction of the Z-axis) the wiring layer 11a, have an opening 19b and an opening 19c, respectively. Each of the opening 19b and the opening 19c is formed by removing a rectangular portion from the wiring layer 11b or 11c corresponding thereto. Each rectangular portion has an area smaller than that of the opening 19a in the wiring layer 11a. The opening 19b and the opening 19c are at the same position in a plan view in the positive direction of the Z-axis. Each of the opening 19b and the opening 19c has a length Hₑ in the X-axis direction and a length Wₑ in the Y-axis direction (see FIG. 4).

The wiring layer 11d is a metal layer on the back side of the module substrate 10 opposite to the wiring layer 11a that is the surface layer. The wiring layer 11d functions as a backshort that reflects an electromagnetic wave travelling in the negative direction of the Z-axis after being emitted from the coupling element 14.

In the above structure, a portion that is equivalent to a part of the rectangular waveguide is formed in the thickness direction (negative direction of the Z-axis) of the module substrate 10. The portion contains a dielectric material as a medium. In order that the wiring layer 11d can be used as a backshort (reflection surface) for frequencies to be used, the thickness of the dielectric layer 12 and/or the number of the metal layers is varied in accordance with the dielectric constant of the dielectric layer 12.

The above structure includes a region R of the dielectric layer surrounded by the via structures between the wiring layer 11a and the wiring layer 11d. For example, the region R has a length Hₑ in the X-axis direction and a length Wₑ in the Y-axis direction. The distance between the wiring layer 11a and the wiring layer 11d is λₑ/4, where λₑ is an effective wavelength of the electromagnetic wave that propagates inside the dielectric layers 12.

Hₑ and Wₑ are determined in accordance with, for example, the size of the waveguide to be connected and the dielectric constant of the dielectric layer.

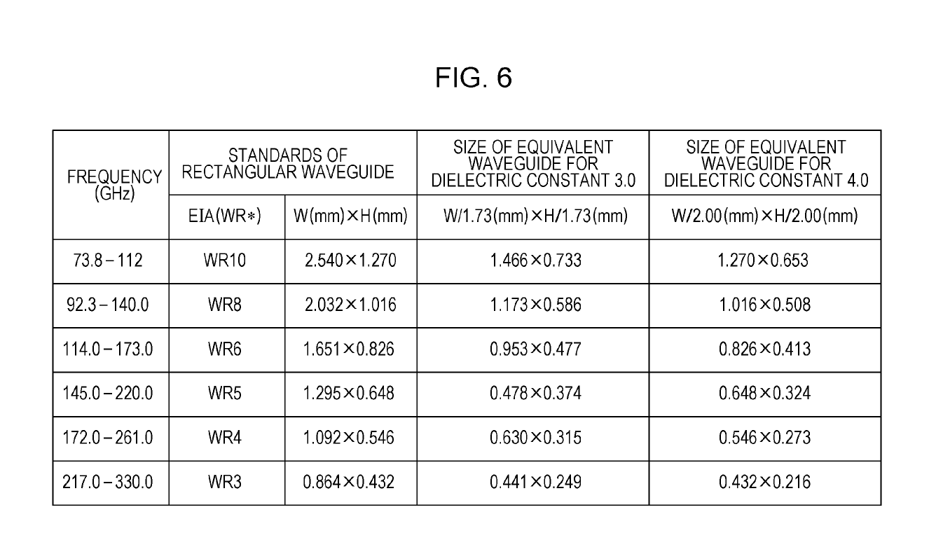

FIG. 6 is a table showing the relation between each standard size of a rectangular waveguide for a high frequency band and a size of the rectangular waveguide in accordance with a dielectric constant. FIG. 6 shows sizes of waveguide equivalent to those in FIG. 3, which are converted from each standard size of the rectangular waveguide on the basis of a dielectric constant of 3.0 and a dielectric constant of 4.0, respectively. Each of the sizes converted from each standard size of the rectangular waveguide on the basis of these dielectric constants corresponds to the size of a waveguide that is filled with a medium having a corresponding dielectric constant and that has the same characteristics as those of a rectangular waveguide having the standard size.

For example, in a case where the dielectric layer has a dielectric constant of 3.0, each of Hₑ and Wₑ may be a length corresponding to a size in FIG. 6 converted on the basis of the dielectric constant of 3.0. However, Hₑ and Wₑ are not limited thereto, provided that Hₑ<H and Wₑ<W.

Such a structure enables optimization of characteristics regarding transmission of electromagnetic waves to the waveguide structure. The characteristics regarding the transmission of electromagnetic waves can also be optimized by employing another material having a different dielectric constant for the dielectric layer 12.

Next, the connection of the rectangular waveguide structure and the CMOS chip to the module substrate 10 will be described.

FIGS. 7A and 7B each illustrate an example of the connection of the CMOS chip 2 and the rectangular waveguide structure 3 to the module substrate 10. FIG. 7A is a plan view, including a set position S for the CMOS chip 2, of the module substrate 10. FIG. 7B illustrates a section of the module substrate 10, taken along line VIIB-VIIB of FIG. 7A, a section of the CMOS chip 2, and a section of the rectangular waveguide structure 3 to be connected to the module substrate 10.

The CMOS chip 2 is connected to the module substrate 10 by flip-chip mounting. The high-frequency terminals 2a on the CMOS chip 2 are connected to the transmission line 13 on the module substrate 10.

The rectangular waveguide structure 3 has the waveguide aperture 3a opposite the wiring layer 11a (surface layer) of the module substrate 10. The rectangular waveguide structure 3 also includes a tube 3b extending in a power propagation direction (positive direction of the Z-axis). The waveguide aperture 3a is at an end portion of the tube 3b. The rectangular waveguide structure 3 is aligned with the coupling element 14 and connected to the module substrate 10. The waveguide aperture 3a of the rectangular waveguide has a length H in the X-axis direction and a length W in the Y-axis direction.

The rectangular waveguide structure 3 is connected in a direction from the positive side toward the negative side of the Z-axis such that the waveguide aperture 3a of the rectangular waveguide structure 3 is aligned with the opening 19a of the wiring layer 11a. The rectangular waveguide structure 3 is thereby integrated with the module substrate 10, to which the CMOS chip 2 has been connected. Such a structure causes the electromagnetic wave emitted from the coupling element 14 to be emitted to the outside through the tube 3b of the rectangular waveguide structure 3.

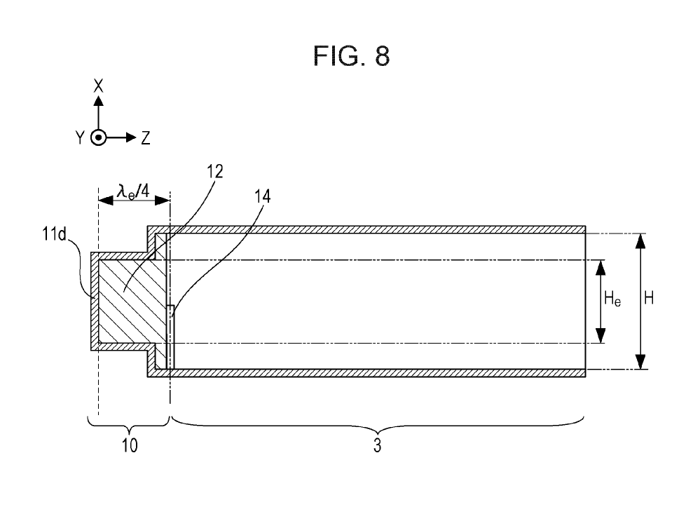

FIG. 8 illustrates an example of the electromagnetic structure of the module substrate 10 according to the first embodiment. FIG. 8 schematically illustrates the module substrate 10 and the rectangular waveguide structure 3 connected to each other, for comparison with the view of the connection between the waveguide and the transmission line in existing techniques in FIG. 2A. Due to the dielectric layer 12 of the module substrate 10, the distance between the coupling element 14 and the backshort (wiring layer 11d) is reduced from λ/4 to λₑ/4, which leads to a reduction in the size of the equivalent rectangular waveguide structure formed in the thickness direction (Z-axis direction).

As described above, according to the first embodiment, a portion equivalent to the waveguide can be formed in accordance with the dielectric constant of the dielectric layer in the module substrate 10 connected to the rectangular waveguide structure 3. Such a structure enables the backshort for the coupling element 14 to be formed inside the module substrate 10. Thus, it is possible to emit the signal in the 100-GHz band or higher into space or collect electric power in space highly efficiently with low loss.

The distance between the coupling element 14 and the backshort (wiring layer 11d) is specified by the thickness of the resin substrate. Even with an existing manufacturing method, approximately ±0.002 mm of the manufacturing variation in the thickness can be achieved. Therefore, the backshort can be formed more simply compared with the alignment mechanism formed by machining.

Moreover, precise aligning of the coupling element 14 with the rectangular waveguide structure 3 can be performed by measuring the position of each alignment marker 18, which is formed inside the opening 19a of the wiring layer 11a, in the positive direction of the Z-axis of the tube 3b of the rectangular waveguide structure 3 by using an optical method. For example, the rectangular waveguide structure 3 can be connected to the module substrate 10 by using a camera to detect the alignment markers 18 in the axial direction of the tube 3b of the rectangular waveguide structure 3 and aligning the position of the waveguide aperture 3a of the rectangular waveguide structure 3 with the detected position. The above method can be automated, and thus can reduce manufacturing costs of the module including the module substrate 10 and the rectangular waveguide structure 3.

The influence of the alignment markers 18 on the electromagnetic wave transmission characteristics can be reduced by forming each alignment marker 18 so as to have a length less than or equal to ⅛ the wavelength of the electromagnetic wave to be used. The influence of the alignment markers 18 on the transmission characteristics can also be reduced by disposing the alignment markers 18 outside the opening 19b of the wiring layer 11b in the view from an upper surface (in the view from the positive side of the Z-axis).

The mechanical strength of the module substrate 10 can be increased by additionally disposing a dielectric substrate or a metal substrate, as a support for the module substrate 10, below the module substrate 10.

### Second Embodiment

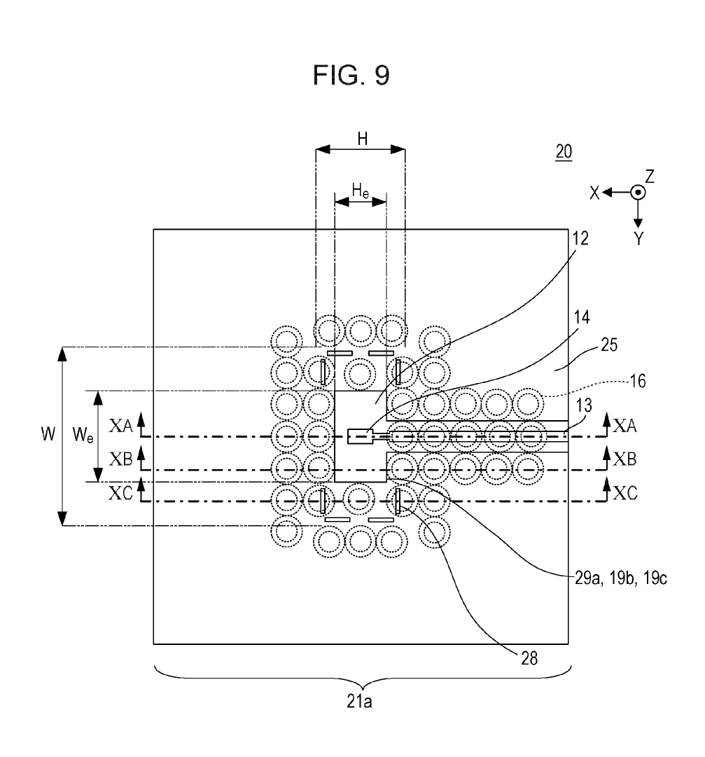

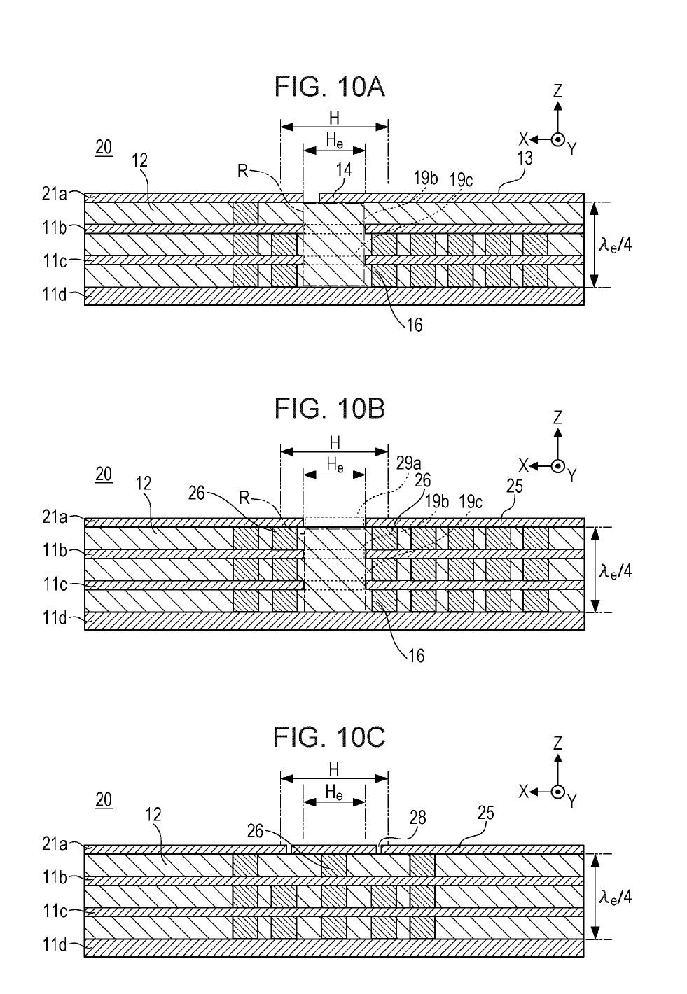

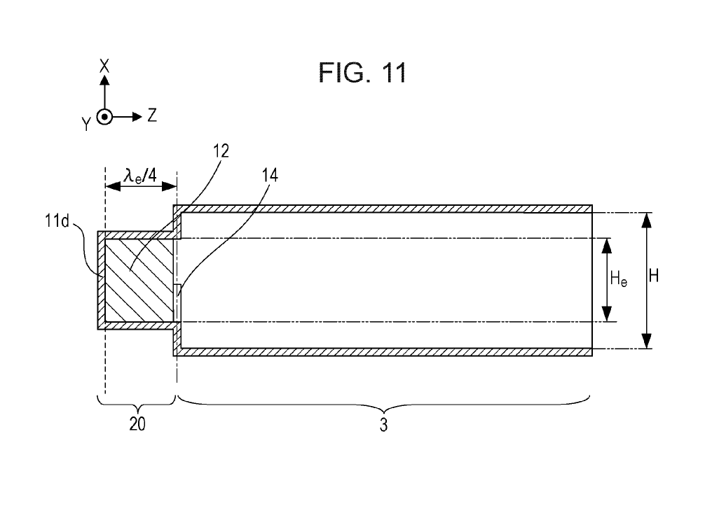

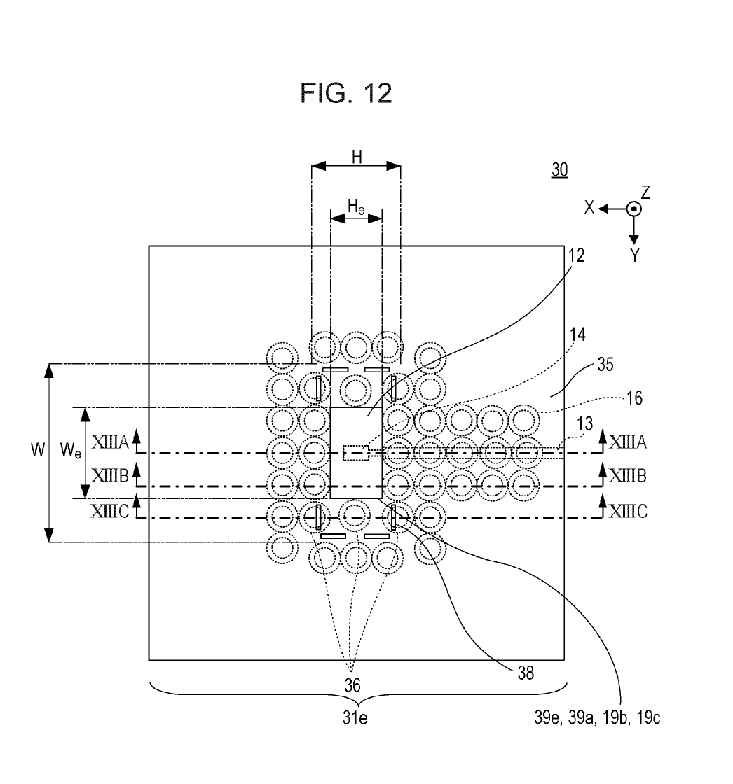

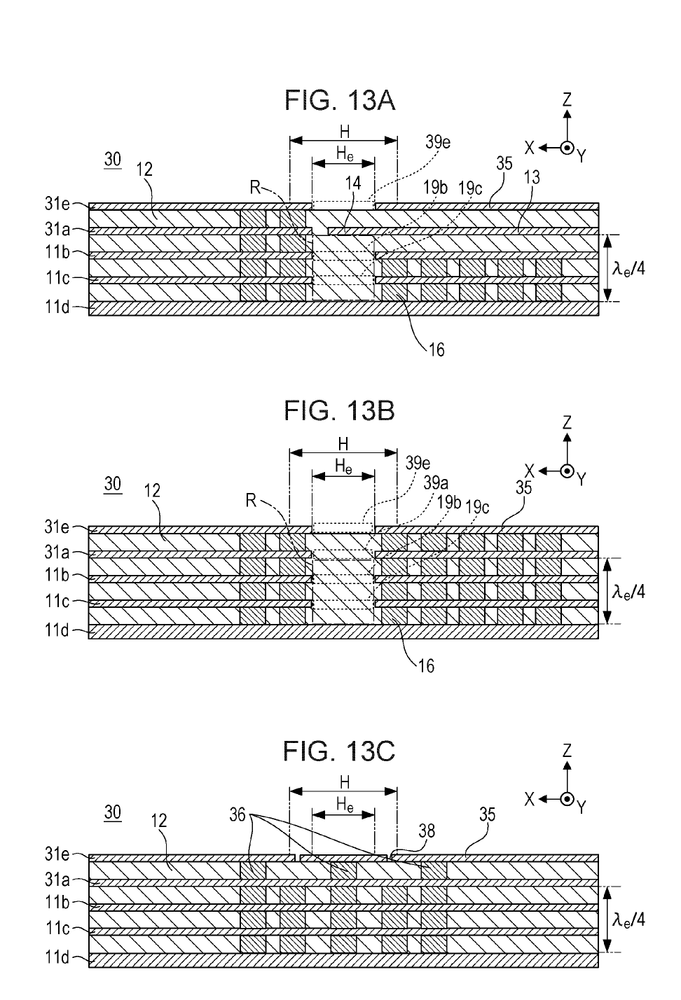

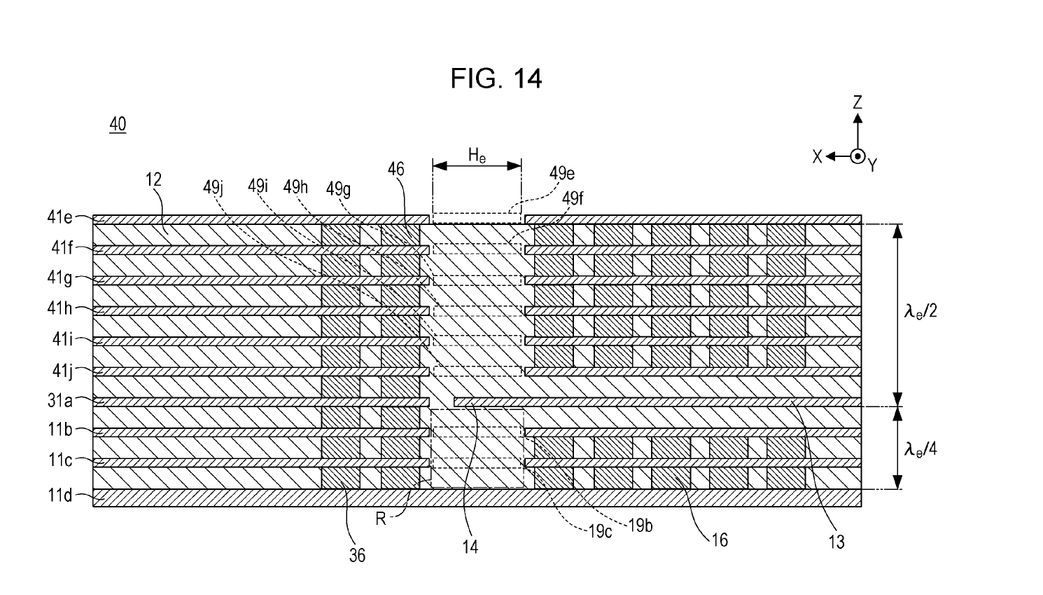

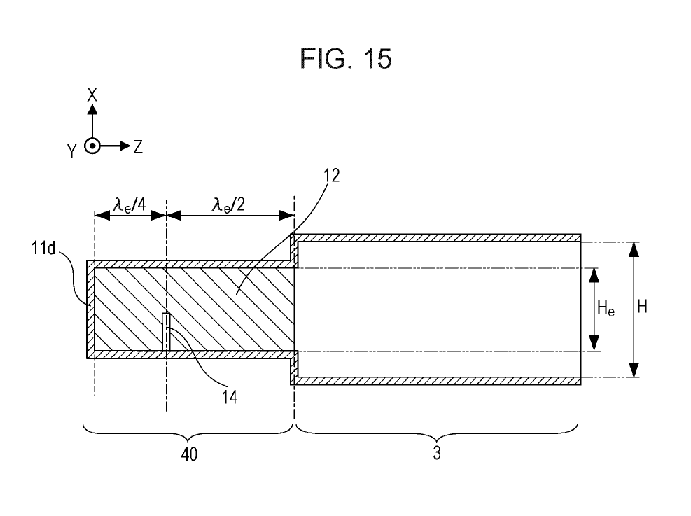

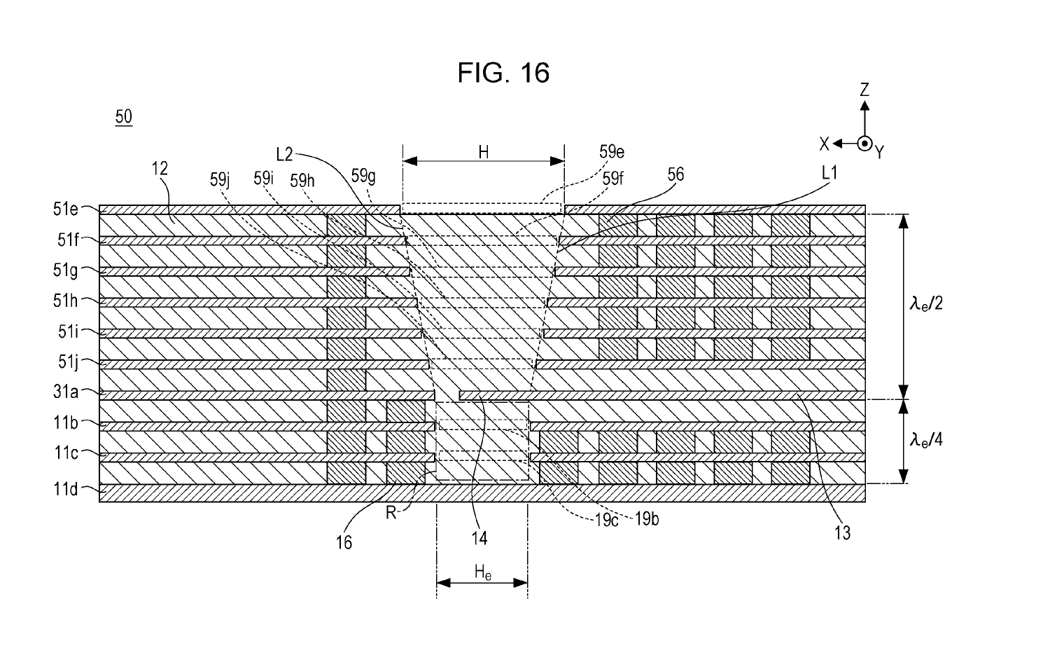

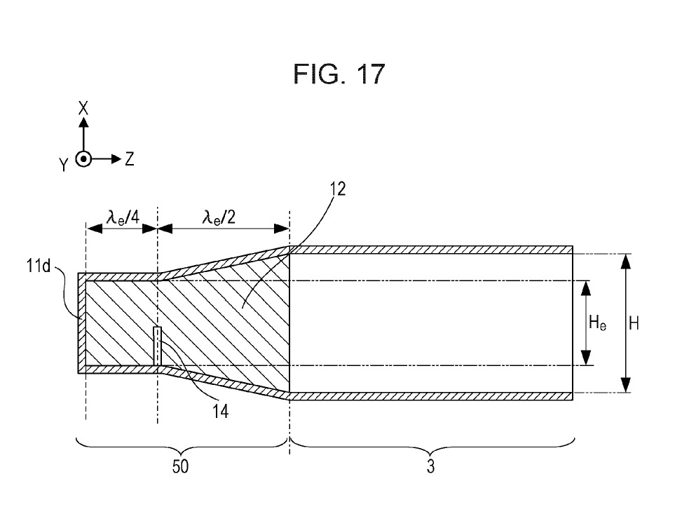

FIG. 9 is a plan view of an example of a module substrate 20 according to a second embodiment of the present disclosure. FIG. 10A is a sectional view taken along line XA-XA of FIG. 9. FIG. 10B is a sectional view taken along line XB-XB of FIG. 9. FIG. 100 is a sectional view taken along line XC-XC of FIG. 9. It is to be noted that in FIG. 9 and FIGS. 10A to 100, components respectively corresponding to the components in FIG. 4 and FIGS. 5A to 5C are given the same reference characters as those of the components in FIG. 4 and FIGS. 5A to 5C, and description thereof will be omitted.

The module substrate 20 differs from the module substrate 10 in that the module substrate 20 includes a wiring layer 21a as a surface layer and via structures 26 between the wiring layer 21a and the wiring layer 11b.

The wiring layer 21a is the surface layer of the module substrate 20 and includes the transmission line 13, the coupling element 14, a ground plane 25, and alignment markers 28.

The transmission line 13 is formed on the wiring layer 21a and connected to the high-frequency terminals 2a (see FIG. 7B) of the CMOS chip 2.

The coupling element 14 is formed at a position at an end portion of the transmission line 13. The position is opposite the waveguide aperture 3a (see FIG. 7B) of the rectangular waveguide structure 3.

The ground plane 25 is formed adjacent to both sides (in the positive and negative directions of the Y-axis) of the transmission line 13. The ground plane 25 is connected to the wiring layers 21a to 11d through the via structures 16 and the via structures 26.

The alignment markers 28 are positioned outside an opening 29a and inside a set position where the waveguide aperture 3a of the rectangular waveguide structure 3 is positioned. The alignment markers 28 are formed by removing portions of a metal pattern of the wiring layer 21a.

A portion of the wiring layer 21a surrounding the coupling element 14 is removed from the wiring layer 21a. The portion has the same shape as the rectangular waveguide in accordance with the reduction in wavelength dependent on the dielectric constant of the dielectric layer 12. The same shape as the rectangular waveguide in accordance with the reduction in wavelength dependent on the dielectric constant is, for example, the shape having the same size as the equivalent waveguide shown in FIG. 6. The wiring layer 21a has the opening 29a surrounding the coupling element 14. The opening 29a has the same shape as the rectangular waveguide in accordance with the reduction in wavelength dependent on the dielectric constant of the dielectric layer 12. The opening 29a has the length Hₑ in the X-axis direction and the length Wₑ in the Y-axis direction.

The via structures 26 are disposed so as to surround the opening 29a formed in the wiring layer 21a.

In the above structure, a portion that is equivalent to a part of the rectangular waveguide is formed in the thickness direction (negative direction of the Z-axis) of the module substrate 20. The portion contains a dielectric material as a medium.

FIG. 11 illustrates an example of an electromagnetic structure of the module substrate 20 according to the second embodiment. FIG. 11 schematically illustrates the module substrate 20 and the rectangular waveguide structure 3 connected to each other, for comparison with the view of the connection between the waveguide and the transmission line in existing techniques in FIG. 2A. Due to the dielectric layer 12 of the module substrate 20, the distance between the coupling element 14 and the backshort (wiring layer 11d) is reduced from λ/4 to λₑ/4, which leads to a reduction in the size of the equivalent rectangular waveguide structure formed in the thickness direction (negative direction of the Z-axis). Moreover, because the opening 29a of the wiring layer 21a has the same shape as the rectangular waveguide in accordance with the reduction in wavelength dependent on the dielectric constant of the dielectric layer 12, a portion between the coupling element 14 and the backshort is continuous.

As described above, according to the second embodiment, a portion equivalent to the waveguide can be formed in accordance with the dielectric constant of the dielectric layer in the module substrate 20 connected to the rectangular waveguide structure 3. Such a structure enables the backshort for the coupling element 14 to be formed inside the module substrate 20. Thus, it is possible to emit the signal in the 100-GHz band or higher into space or collect electric power in space highly efficiently with low loss.

Moreover, precise aligning of the coupling element 14 with the waveguide aperture 3a of the rectangular waveguide structure 3 can be performed by measuring the position of each alignment marker 28, which are formed outside the opening 29a of the wiring layer 21a by removing the portions of the metal pattern, in the positive direction of the Z-axis of the tube 3b of the rectangular waveguide structure 3 by using an optical method. The influence of the alignment markers 28 on the transmission characteristics can be reduced by forming the alignment markers 28 outside the opening 29a of the wiring layer 21a.

Moreover, the alignment markers 28 formed outside the opening 29a can reduce the size of the opening 29a of the wiring layer 21a so as to be smaller than the size of the waveguide aperture 3a of the rectangular waveguide structure 3. Thus, when being connected to the rectangular waveguide structure 3, the module substrate 20 comes into close contact with the rectangular waveguide structure 3, which can improve electrical characteristics.

### Third Embodiment

FIG. 12 is a plan view of an example of a module substrate 30 according to a third embodiment of the present disclosure. FIG. 13A is a sectional view taken along line XIIIA-XIIIA of FIG. 12. FIG. 13B is a sectional view taken along line XIIIB-XIIIB of FIG. 12. FIG. 13C is a sectional view taken along line XIIIC-XIIIC of FIG. 12. It is to be noted that in FIG. 12 and FIGS. 13A to 13C, components respectively corresponding to the components in FIG. 9 and FIGS. 10A to 100 are given the same reference characters as those of the components in FIG. 9 and FIGS. 10A to 10C, and description thereof will be omitted.

The module substrate 30 includes a wiring layer 31a and a wiring layer 31e instead of the wiring layer 21a, which is the surface layer of the module substrate 20. The module substrate 30 additionally includes via structures 36 that connect the wiring layer 31a and the wiring layer 31e to each other.

The wiring layer 31a includes the transmission line 13 and the coupling element 14.

The transmission line 13 is formed on the wiring layer 31a and connected to the high-frequency terminals 2a (see FIG. 7B) of the CMOS chip 2.

The coupling element 14 is formed at a position at an end portion of the transmission line 13. The position is opposite the waveguide aperture 3a (see FIG. 7B) of the rectangular waveguide structure 3.

A portion of the wiring layer 31a surrounding the coupling element 14 is removed from the wiring layer 31a. The portion has the same shape as the opening of the rectangular waveguide in accordance with the reduction in wavelength dependent on the dielectric constant of the dielectric layer 12. The wiring layer 31a has an opening 39a surrounding the coupling element 14. The opening 39a has the same shape as the rectangular waveguide in accordance with the reduction in wavelength dependent on the dielectric constant of the dielectric layer 12. The opening 39a has the length Hₑ in the X-axis direction and the length Wₑ in the Y-axis direction.

The wiring layer 31e is a surface of the module substrate 30 and is a contact surface that covers the transmission line 13 and the coupling element 14. The wiring layer 31e includes a ground plane 35 and alignment markers 38.

The ground plane 35 is connected to the wiring layers 31e to 11d through the via structures 16 and the via structures 36.

The alignment markers 38 are positioned outside an opening 39e and inside a set position where the waveguide aperture 3a of the rectangular waveguide structure 3 is positioned. The alignment markers 38 are formed by removing portions of a metal pattern of the wiring layer 31e.

The CMOS chip 2 (see FIG. 7B) is connected to the wiring layer 31e and further connected to the transmission line 13 of the wiring layer 31a through the via structures 36 that connects the wiring layer 31e and the wiring layer 31a to each other.

The wiring layer 31e has the opening 39e at a position in which the opening 39a of the wiring layer 31a is projected in the positive direction of the Z-axis. The opening 39e is formed by removing a portion from the wiring layer 31e. The portion has the same shape as the rectangular waveguide in accordance with the reduction in wavelength dependent on the dielectric constant of the dielectric layer 12. The opening 39e has a length Hₑ in the X-axis direction and a length Wₑ in the Y-axis direction.

The via structures 36 are disposed so as to surround the opening 39e formed in the wiring layer 31e and the opening 39a formed in the wiring layer 31a. The via structures 36 are electrically connected to other wiring layers.

In the above structure, a portion that is equivalent to a part of the rectangular waveguide is formed in the thickness direction (negative direction of the Z-axis) of the module substrate 30. The portion contains a dielectric material as a medium.

As described above, according to the third embodiment, a portion equivalent to the waveguide can be formed in accordance with the dielectric constant of the dielectric layer in the module substrate 30 connected to the rectangular waveguide structure 3. Such a structure enables the backshort for the coupling element 14 to be formed inside the module substrate 30. Thus, it is possible to emit the signal in the 100-GHz band or higher into space or collect electric power in space highly efficiently with low loss.

The via structures 36 are additionally disposed so as to surround the opening 39e formed in the wiring layer 31e. The via structures 36 enable the module substrate 30 to come into close contact with the rectangular waveguide structure 3 opposite the module substrate 30. Thus, electrical characteristics of a coupling portion between the module substrate 30 and the rectangular waveguide structure 3 can be improved.

### Fourth Embodiment

FIG. 14 is a sectional view of an example of a module substrate 40 according to a fourth embodiment of the present disclosure. The plan view of the module substrate 40 is the same as the plan view of the module substrate 30 in FIG. 12. FIG. 14 is a sectional view of the module substrate 40, the view corresponding to the sectional view taken along line XIIIA-XIIIA of FIG. 12. It is to be noted that in FIG. 14, components respectively corresponding to the components in FIG. 12 and FIGS. 13A to 13C are given the same reference characters as those of the components in FIG. 12 and FIGS. 13A to 13C, and description thereof will be omitted.

The module substrate 40 includes wiring layers 41e to 41j instead of the wiring layer 31e, which is the surface layer of the module substrate 30. The module substrate 40 additionally includes via structures 46 that form a connection between the wiring layer 41e and the wiring layer 41j.

The wiring layer 41e is a surface layer of the module substrate 40 and includes alignment markers (see FIG. 12). The distance between the wiring layer 41e, which is the surface layer, and the wiring layer 31a, which includes the coupling element 14, is λₑ/2.

The CMOS chip 2 (see FIG. 7B) is connected to the wiring layer 41e and further connected to the transmission line 13 of the wiring layer 31a through the via structures 46 that form the connection between the wiring layer 41e and the wiring layer 41j and the via structures 36 that connect the wiring layer 41j and the wiring layer 31a to each other.

The wiring layer 41e has an opening 49e at a position in which the opening 39a (see FIG. 13B) of the wiring layer 31a is projected in the positive direction of the Z-axis. The opening 49e is formed by removing a portion from the wiring layer 41e. The portion has the same shape as the rectangular waveguide in accordance with the reduction in wavelength dependent on the dielectric constant of the dielectric layer 12. The opening 49e has a length Hₑ in the X-axis direction and a length Wₑ in the Y-axis direction (see FIG. 12).

The wiring layers 41f to 41j also have openings 49f to 49j, respectively, at corresponding positions in which the opening 39a of the wiring layer 31a is projected in the positive direction of the Z-axis. Each of the openings 49f to 49j is formed by removing a portion from the wiring layers 41f to 41j corresponding thereto. Each of the portions has the same shape as the rectangular waveguide in accordance with the reduction in wavelength dependent on the dielectric constant of the dielectric layer 12.

The via structures 46 are disposed so as to surround the openings 49e to 49j and the opening 39a (see FIG. 13B) that is formed in the wiring layer 31a. The via structures 46 are electrically connected to other wiring layers.

In the above structure, a portion that is equivalent to a part of the rectangular waveguide is formed in the thickness direction (positive and negative directions of the Z-axis) of the module substrate 40. The portion contains a dielectric material as a medium.

FIG. 15 illustrates an example of an electromagnetic structure of the module substrate 40 according to the fourth embodiment. FIG. 15 schematically illustrates the module substrate 40 and the rectangular waveguide structure 3 connected to each other, for comparison with the view of the connection between the waveguide and the transmission line in existing techniques in FIG. 2A. Due to the dielectric layer 12 of the module substrate 40, the distance between the coupling element 14 and the backshort (wiring layer 11d) is reduced from λ/4 to λₑ/4, which leads to a reduction in the size of the equivalent rectangular waveguide structure formed in the thickness direction (negative direction of the Z-axis) from λ/2 to λₑ/2. Moreover, the wiring layers 41e to 41j positioned above (positive direction of the Z-axis) the wiring layer 31a, on which the coupling element 14 is formed, form an equivalent waveguide structure having a length of λₑ/2 and extending from the coupling element 14 in an emission direction (positive direction of the Z-axis).

As described above, according to the fourth embodiment, a portion equivalent to the waveguide can be formed in accordance with the dielectric constant of the dielectric layer in the module substrate 40 connected to the rectangular waveguide structure 3. Such a structure enables the backshort for the coupling element 14 to be formed inside the module substrate 40. Thus, it is possible to emit the signal in the 100-GHz band or higher into space or collect electric power in space highly efficiently with low loss.

The influence of impedance mismatching, which occurs at a border between the dielectric layer 12 and the air, on the coupling element 14 can be reduced by the equivalent waveguide structure having the length of λₑ/2 and extending from the coupling element 14 toward an emission direction side, the equivalent waveguide structure being formed by the wiring layers 41e to 41j positioned above (positive direction of the Z-axis) the wiring layer 31a, on which the coupling element 14 is formed.

### Fifth Embodiment

FIG. 16 is a sectional view of an example of a module substrate 50 according to a fifth embodiment of the present disclosure. The plan view of the module substrate 50 is the same as the plan view of the module substrate 10 in FIG. 4, except for the feature wherein the coupling element 14 and the transmission line 13 are disposed on an inner layer. FIG. 16 is a sectional view of the module substrate 50, the view corresponding to the sectional view taken along line VA-VA of FIG. 4.

The module substrate 50 shares the same feature wherein a plurality of wiring layers is disposed above (positive direction of the Z-axis) the wiring layer 31a, on which the coupling element 14 is disposed. Thus, in FIG. 16, components respectively corresponding to the components in FIG. 14 are given the same reference characters as those of the components in FIG. 14, and description thereof will be omitted.

The module substrate 50 includes wiring layers 51e to 51j instead of the wiring layers 41e to 41j of the module substrate 40.

The wiring layer 51e is a surface layer of the module substrate 50 and includes alignment markers (see FIG. 4). The distance between the wiring layer 51e, which is the surface layer, and the wiring layer 31a, which includes the coupling element 14, is λₑ/2.

The CMOS chip 2 (see FIG. 7B) is connected to the wiring layer 51e and further connected to the transmission line 13 of the wiring layer 31a through via structures 56 that form a connection between the wiring layer 51e and the wiring layer 51j and the via structures 36 that connect the wiring layer 51j and the wiring layer 31a to each other.

The wiring layer 51e has an opening 59e. The opening 59e is formed by removing a portion from the wiring layer 51e and has the same shape as the rectangular waveguide. The opening 59e has a length H in the X-axis direction and a length W in the Y-axis direction (See FIG. 4).

The wiring layers 51f to 51j have openings 59f to 59j, respectively. Each of the openings 59f to 59j is formed by removing a portion of a metal pattern of the wiring layers 51f to 51j corresponding thereto. The sizes of the metal patterns become smaller from the wiring layer 51f toward the wiring layer 51j such that the openings 59e to 39a (see FIG. 13B) of the wiring layers 51e to 31a are continuous to each other. For example, in the sectional view in FIG. 16, a portion between the straight line L1 connecting an edge of the opening 59e and an edge of the opening 39a and the straight line L2 connecting another edge of the opening 59e and another edge of the opening 39a are removed to form the openings 59f to 59j.

The via structures 56 are disposed so as to surround the openings 59e to 59j and the opening 39a that is formed in the wiring layer 31a. The via structures 56 are electrically connected to the other wiring layers.

In the above structure, a portion that is equivalent to a part of the rectangular waveguide is formed in the thickness direction (positive and negative directions of the Z-axis) of the module substrate 50. The portion contains a dielectric material as a medium.

FIG. 17 illustrates an example of an electromagnetic structure of the module substrate 50 according to the fifth embodiment. FIG. 17 schematically illustrates the module substrate 50 and the rectangular waveguide structure 3 connected to each other, for comparison with the view of the connection between the waveguide and the transmission line in existing techniques in FIG. 2A. Due to the dielectric layer 12 of the module substrate 50, the distance between the coupling element 14 and the backshort (wiring layer 11d) is reduced from λ/4 to λₑ/4, which leads to a reduction in the size (the length in the Z-axis direction) of the equivalent rectangular waveguide structure formed in the thickness direction (negative direction of the Z-axis) from λ/2 to λₑ/2. The wiring layers 51e to 51j positioned above (positive direction of the Z-axis) the wiring layer 31a, on which the coupling element 14 is formed, form a tapered (horn-shaped) equivalent waveguide structure having a length of λₑ/2 and extending from the coupling element 14 in the emission direction (positive direction of the Z-axis).

As described above, according to the fifth embodiment, a portion equivalent to the waveguide can be formed in accordance with the dielectric constant of the dielectric layer in the module substrate 50 connected to the rectangular waveguide structure 3. Such a structure enables the backshort for the coupling element 14 to be formed inside the module substrate 50. Thus, it is possible to emit the signal in the 100-GHz band or higher into space or collect electric power in space highly efficiently with low loss.

The structural discontinuity of the connection between the equivalent waveguide structure and the rectangular waveguide structure 3 in the module substrate 50 is reduced by the tapered (horn-shaped) equivalent waveguide structure having a length of λₑ/2 and extending from the coupling element 14 in the emission direction, the tapered (horn-shaped) equivalent waveguide structure being formed by the wiring layers 51e to 51j positioned above (positive direction of the Z-axis) the wiring layer 31a, on which the coupling element 14 is formed. Thus, electromagnetic waves can be favorably transmitted.

The embodiments have been described above with reference to the drawings; however, it is a matter of course that the present disclosure is not limited thereto. A person skilled in the art may obviously conceive various modifications and corrections within the scope disclosed in the claims. Such modifications and corrections are naturally considered to be within the technical scope of the present disclosure. Moreover, the components in the embodiments may be selectively combined with each other, provided that the combination does not deviate from the disclosed idea.

### SUMMARY OF THE PRESENT DISCLOSURE

A module substrate according to the present disclosure includes a surface layer to which a rectangular waveguide structure having a waveguide aperture is to be connected; a plurality of metal layers that are stacked with a dielectric layer between each adjacent pair of the metal layers; and a plurality of vias each connecting a corresponding adjacent pair of the metal layers to each other. The plurality of metal layers include a first metal layer and a second metal layer. The first metal layer includes a transmission line and a coupling element at a portion of the transmission line. The second metal layer is positioned further than the first metal layer from the rectangular waveguide structure. The surface layer has a first opening that is to be located to face the waveguide aperture. The first opening surrounds the coupling element in a plan view from the surface layer. A region of the dielectric layer is formed within an area in which the first opening is projected between the first metal layer and the second metal layer. The region is surrounded by some of the plurality of vias. The size of the region in the plan view is smaller than the size of the waveguide aperture.

In the module substrate according to the present disclosure, the distance between the first metal layer and the second metal layer is determined on the basis of, at least, the dielectric constant of the dielectric layer and the wavelength of an electromagnetic wave to be emitted from the coupling element.

In the module substrate according to the present disclosure, the surface layer includes a marker for positioning the rectangular waveguide structure. The marker is disposed in accordance with the size of the waveguide aperture.

In the module substrate according to the present disclosure, the surface layer is the first metal layer.

In the module substrate according to the present disclosure, the first opening has a size equal to the size of the waveguide aperture. The rectangular waveguide structure is to be connected to the module substrate by aligning the waveguide aperture and the first opening with each other.

In the module substrate according to the present disclosure, the first opening has a size equal to the size of the region. The rectangular waveguide structure is to be connected to the module substrate by positioning the waveguide aperture outside the first opening.

In the module substrate according to the present disclosure, the surface layer is one of the metal layers positioned further than the first metal layer from the second metal layer.

In the module substrate according to the present disclosure, the distance between the surface layer and the first metal layer is determined on the basis of the dielectric constant of the dielectric layer and the wavelength of an electromagnetic wave to be emitted from the coupling element.

In the module substrate according to the present disclosure, the first opening has a size equal to the size of the region. The rectangular waveguide structure is to be connected to the module substrate by coinciding the waveguide aperture and the first opening with each other.

In the module substrate according to the present disclosure, the first opening has a size equal to the size of the waveguide aperture. The first metal layer has a second opening having a size equal to the size of the region. At least one of the metal layers between the first metal layer and the second metal layer has an opening along a line connecting the first opening and the second opening.

The present disclosure is applicable to a module for high-speed wireless communication or a module for a high-resolution radar system.

What is claimed is:

1. A module substrate comprising:
a surface layer to which a rectangular waveguide structure having a waveguide aperture is to be connected;
a plurality of metal layers that are stacked with a dielectric layer between each adjacent pair of the metal layers, the plurality of metal layers including
a first metal layer including a transmission line and a coupling element formed at a portion of the transmission line, and
a second metal layer positioned further than the first metal layer from the rectangular waveguide structure; and
a plurality of vias each connecting a corresponding adjacent pair of the metal layers to each other,
wherein the surface layer has a first opening that is to be located to face the waveguide aperture, the first opening surrounding the coupling element in a plan view from the surface layer,
wherein a region of the dielectric layer is formed within an area in which the first opening is projected between the first metal layer and the second metal layer, the region being surrounded by some of the plurality of vias, and
wherein a size of the region in the plan view is smaller than a size of the waveguide aperture.

2. The module substrate according to claim 1,
wherein a distance between the first metal layer and the second metal layer is determined based on, at least, a dielectric constant of the dielectric layer and a wavelength of an electromagnetic wave to be emitted from the coupling element.

3. The module substrate according to claim 1,
wherein the surface layer includes
a marker for positioning the rectangular waveguide structure, the marker being disposed in accordance with the size of the waveguide aperture.

4. The module substrate according to claim 1,
wherein the surface layer is the first metal layer.

5. The module substrate according to claim 1,
wherein the first opening has a size equal to the size of the waveguide aperture, and
wherein the rectangular waveguide structure is to be connected to the module substrate by aligning the waveguide aperture and the first opening with each other.

6. The module substrate according to claim 1,
wherein the first opening has a size equal to the size of the region, and
wherein the rectangular waveguide structure is to be connected to the module substrate by positioning the waveguide aperture outside the first opening.

7. The module substrate according to claim 1,
wherein the surface layer is one of the metal layers positioned further than the first metal layer from the second metal layer.

8. The module substrate according to claim 7,
wherein a distance between the surface layer and the first metal layer is determined based on a dielectric constant of the dielectric layer and a wavelength of an electromagnetic wave to be emitted from the coupling element.

9. The module substrate according to claim 7,
wherein the first opening has a size equal to a size of the region, and
wherein the rectangular waveguide structure is to be connected to the module substrate by coinciding the waveguide aperture and the first opening with each other.

10. The module substrate according to claim 8,
wherein the first opening has a size equal to a size of the waveguide aperture,
wherein the first metal layer has a second opening having a size equal to a size of the region, and
wherein at least one of the metal layers between the first metal layer and the second metal layer has an opening along a line connecting the first opening and the second opening.
